(19) United States
(12) Patent Application Publication
(10) Pub. No.: US 2005/0208706 A1
(43) Pub. Date: Sep. 22, 2005

(54) Method of creating multi-layered monolithic circuit structure containing integral buried and trimmed components

(76) Inventors: Roy J. Blazek, Overland Park, KS (US); Gregory Eugene Barner, Overland Park, KS (US); Sam William Bandler, Olathe, KS (US); Eric Eubank, Lee's Summit, MO (US); Fernando Uribe, Albuquerque, NM (US); Patrick A. Smith, Albuquerque, NM (US)

Correspondence Address: Hovey Williams LLP, Suite 400, 2405 Grand Blvd., Kansas City, MO, 64108, US

(21) Appl. No.: 10/802,203

(22) Filed: Mar. 17, 2004

(51) Int. Cl. H01L 21/44; H01L 21/48; H01L 21/50; H01L 23/48; H01L 23/52; H01L 29/40

(52) U.S. Cl. 438/109

(57) ABSTRACT

A method of creating a multi-layered monolithic circuit structure wherein individual layers of standard alumina thick film ceramic substrate and the resistors, inductors, capacitors, and other circuit componentry printed thereon are fired, and the circuit componentry trimmed or otherwise adjusted to achieve a desired degree of precision prior to combining the layers with a thick film glass bonding agent to form the monolithic structure.

### FEDERALLY SPONSORED RESEARCH OR DEVELOPMENT PROGRAM

The present invention was developed with support from the U.S. government under Contract No. DE-AC04-01AL66850 with the U.S. Department of Energy. Accordingly, the U.S. government has certain rights in the present invention.

### BACKGROUND OF THE INVENTION

1. Field of the Invention

The present invention relates broadly to methods, techniques, and processes for creating multi-layered monolithic circuit structures. More particularly, the present invention concerns a method of creating a multi-layered monolithic circuit structure wherein individual layers of thick film ceramic substrate and circuit componentry printed thereon are fired, and the circuit componentry trimmed or otherwise adjusted to achieve a desired degree of precision prior to combining the layers with a bonding agent to form the monolithic structure.

2. Description of the Prior Art

It is often desirable to combine multiple microcircuits into a single monolithic structure in order to reduce the volume needed to accommodate the microcircuits and increase circuit density while maintaining desired electrical performance criteria. These advantages are important in a number of fields, including, for example, aerospace, automotive, computer, medical equipment, and consumer electronics.

In the prior art, two basic technologies, thick film technology and low temperature co-fired ceramic (LTCC) technology, are used to fabricate hybrid microcircuits and ceramic multichip modules (MCM-C). Thick film technology involves screen-printing circuit components onto the surface of a fired ceramic substrate, which facilitates post-print trimming. Trimming the circuit components is the process of adjusting their electrical characteristics or values within precise limits by modifying their geometries, typically with a laser. Trimming, however, requires physical access to the circuit components, which can require significant amounts of substrate surface area and necessitates only a single-layer circuit structure.

LTCC technology provides the ability to create multi-layered monolithic structures by co-firing unfired pieces of ceramic substrate onto which circuit components have been printed, thereby combining the substrates to form the monolithic structure. As a result, circuit density is increased and required substrate surface area is reduced. Unfortunately, it is not possible to trim those circuit components located on internal layers buried within the monolithic structure, and therefore the desired degree of precision cannot be obtained. One prior art solution to this problem is to create “windows” or other openings in the outer layers through which the circuit components of the inner layers can be accessed. Unfortunately, these windows eliminate a substantial amount of valuable space or “real estate” on the upper layers, and thereby undermine achieving the reduced volume and higher circuit densities that make creating the monolithic structure desirable.

Due to the above-identified and other problems and disadvantages in the art, a need exists for an improved method of creating multi-layered monolithic circuit structures.

### SUMMARY OF THE INVENTION

The present invention overcomes the above-described and other problems and disadvantages in the prior art with an improved method of creating a multi-layered monolithic circuit structure that allows for trimming or otherwise adjusting circuit components on all layers of the monolithic circuit structure in order to achieve a desired degree of precision.

The monolithic structure created using the method of the present invention broadly comprises the circuit components placed onto a plurality of individual layers of substrate, and a bonding agent to bond the individual layers together to form the monolithic structure. The circuit components cooperate to form a microcircuit or portion of the microcircuit, and may be, for example, screen-printed resistors, inductors, or capacitors. The individual layers of substrate support the circuit components, and are preferably pre-fired, thick film ceramic substrate. The bonding agent bonds the layers together to form the final monolithic structure, and is preferably a thick film glass bonding agent.

The monolithic structure is created by first screen-printing the circuit components onto the individual layers of substrate. Then the individual layers and the circuit components printed thereon are fired. Next, the circuit components are trimmed to achieve the desired degree of precision. Such trimming is facilitated by the fact that the circuit components are at this point fully accessible because the layers have not yet been bonded together. Then the thick film glass bonding agent is applied to each of the layers and the layers are assembled in the form of the monolithic structure. Lastly, the assembly of layers is fired to sinter the thick film glass, thereby bonding the individual layers together to create the monolithic structure.

It will be appreciated that the present invention provides a number of substantial advantages over the prior art, including, for example, allowing for the creation of a monolithic circuit structure comprising multiple thick film microcircuits that occupies a smaller volume and achieves a higher circuit density than was possible with prior art fabrication techniques. Furthermore, the present invention allows for the incorporation of thick film screen-printed circuit components within the monolithic circuit structure, thereby advantageously increasing useable circuit area and, ultimately, circuit density. Additionally, the present invention enables trimming the thick film circuit components to precise values prior to final assembly, thereby advantageously enhancing circuit performance. This is accomplished without creating “windows” or other openings as was done in the prior art, and therefore does not undermine achieving the reduced volume and higher circuit densities that make creating the monolithic structure desirable. Furthermore, the present invention advantageously allows for using standard thick film ceramic substrate rather than LTCC substrate or printed wire board (PWB).

These and other important features of the present invention are more fully described in the section titled DETAILED DESCRIPTION OF A PREFERRED EMBODIMENT, below.

### BRIEF DESCRIPTION OF THE DRAWINGS

A preferred embodiment of the present invention is described in detail below with reference to the attached drawing figures, wherein:

FIG. 1 is an exploded isometric view of a multi-layered monolithic circuit structure created using a preferred embodiment of the method of the present invention; and

FIG. 2 is a flowchart setting forth a series of steps involved in practicing the method of the present invention.

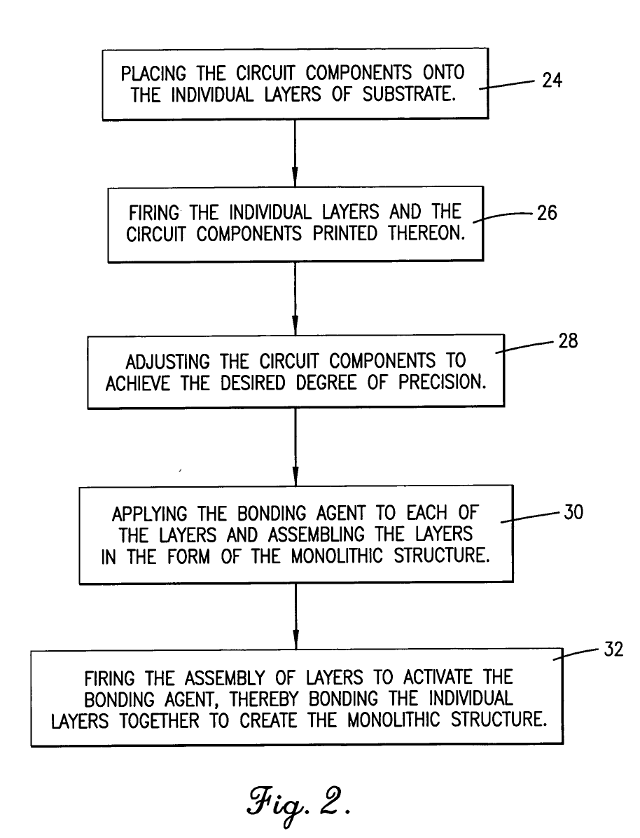

### DETAILED DESCRIPTION OF A PREFERRED EMBODIMENT

With reference to the figures, a method of creating a multi-layered monolithic circuit structure 10 is described, shown, and otherwise disclosed in accordance with a preferred embodiment of the present invention. Broadly, the method advantageously allows for trimming or otherwise adjusting circuit components 12 on all layers of the monolithic circuit structure 10 in order to achieve a desired degree of precision.

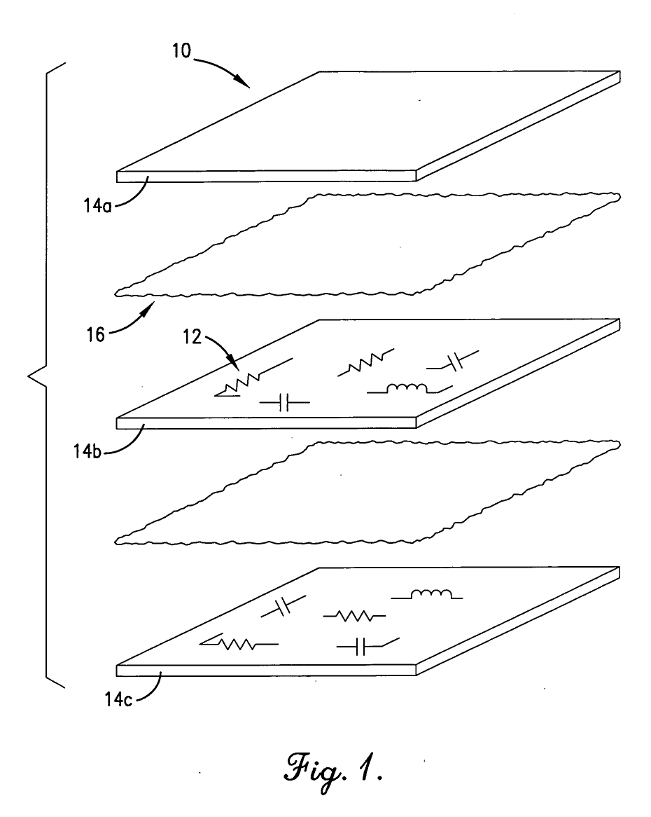

Referring particularly to FIG. 1, the monolithic structure 10 created using the method of the present invention broadly comprises the circuit components 12 placed onto a plurality of individual layers 14a,14b,14c of substrate, and a bonding agent 16 to bond the individual layers 14a,14b,14c together to form the monolithic structure 10.

The circuit components 12 cooperate to form a microcircuit or portion of the microcircuit. The circuit components 12 may be, for example, resistors, inductors, or capacitors, and may be screen-printed or otherwise placed onto the layers 14a,14b,14c using conventional techniques. It will be appreciated that following printing and firing, it is often desirable or necessary to trim (as with, e.g., a laser) or otherwise adjust the circuit components 12 in order to achieve a desired degree of precision.

The individual layers 14a,14b,14c of substrate support the circuit components 12. The layers 14a,14b,14c are preferably pre-fired, standard 99.5% alumina thick film ceramic substrate, though it will be appreciated that other suitable substrate material may be used as desired. It will also be appreciated that the physical characteristics (e.g., size and shape) and number of the layers 14a,14b,14c are, for the most part, design dependent considerations, such that the present invention is not limited to any particulars in this regard.

The bonding agent 16 bonds the layers 14a,14b,14c together to form the final monolithic structure 10. The bonding agent 16 is preferably a thick film glass, though it will be appreciated that other suitable bonding agents or materials may be used as desired.

As mentioned, the monolithic structure 10 is created in a series of steps that correspond to a preferred embodiment of the method of the present invention and which proceed as follows. First, the circuit components 12 are placed onto the individual layers 14a,14b,14c of substrate using a conventional technique, as depicted in box 24. Then the individual layers 14a,14b,14c and the circuit components 12 printed thereon are fired using a conventional thick film processing technique, as depicted in box 26. It will be appreciated that the layers 14a,14b,14c need not be fired simultaneously, because, unlike in the prior art, this initial firing step is not to produce the monolithic structure but rather to set the circuit components 12 so that they may be trimmed. Next, the circuit components 12 are trimmed or otherwise adjusted to achieve the desired degree of precision, as depicted in box 28. This step is facilitated by the fact that the circuit components 12 are at this point fully accessible because the layers 14a,14b,14c have not yet been bonded together. Then the bonding agent 16 is applied to each of the layers 14a,14b,14c and the layers 14a,14b,14c are assembled in the form of the monolithic structure 10, as depicted in box 30. Lastly, the assembly of layers 14a,14b,14c is fired to sinter or otherwise activate the bonding agent 16, thereby bonding the individual layers 14a,14b,14c together to create the monolithic structure 10, as depicted in box 32. Applications for the present invention include manufacturing thick film electronics for aerospace, automotive, computer, medical equipment, and consumer electronics.

From the preceding discussion it will be appreciated that the present invention provides a number of substantial advantages over the prior art, including, for example, allowing for the creation of a monolithic circuit structure comprising multiple thick film microcircuits that occupies a smaller volume and achieves a higher circuit density than was possible with prior art fabrication techniques. Furthermore, the present invention allows for the incorporation of thick film screen-printed circuit components within the monolithic circuit structure, thereby advantageously increasing useable circuit area and, ultimately, circuit density. Additionally, the present invention enables trimming the thick film circuit components to precise values prior to final assembly, thereby advantageously enhancing circuit performance. This is accomplished without creating “windows” or other openings as was done in the prior art, and therefore does not undermine achieving the reduced volume and higher circuit densities that make creating the monolithic structure desirable. Furthermore, the present invention advantageously allows for using standard thick film ceramic substrate rather than LTCC substrate or PWB.

Although the invention has been described with reference to the preferred embodiments illustrated in the attached drawings, it is noted that equivalents may be employed and substitutions made herein without departing from the scope of the invention as recited in the claims. It will be appreciated, for example, that the present invention is not limited to particular kinds of microcircuits or circuit components.

1. A method of creating a monolithic circuit structure, the method comprising the steps of:
(a) placing a circuit component onto an individual layer of substrate;
(b) firing the individual layer of substrate and the circuit component placed thereon;
(c) adjusting the circuit component as necessary to achieve a desired degree of precision;
(d) applying a bonding agent to the individual layer of substrate and assembling the individual layer of substrate with one or more other layers of substrate; and
(e) firing the assembled individual layer of substrate and one or more other layers of substrate together to activate the bonding agent, thereby bonding the individual layer of substrate to the one or more other layers of substrate and creating the monolithic circuit structure.

2. The method as set forth in claim 1, wherein the circuit component is selected from the group consisting of: resistors, capacitors, and inductors.

3. The method as set forth in claim 1, wherein the circuit component is placed onto the individual layer of substrate by screen-printing.

4. The method as set forth in claim 1, wherein the individual layer of substrate and the one or more other layers of substrate are pre-fired thick film ceramic substrate.

5. The method as set forth in claim 4, wherein the individual layer of substrate and the one or more other layers of substrate are standard alumina thick film ceramic substrates.

6. The method as set forth in claim 1, wherein the bonding agent is a thick film glass.

7. A method of creating a multi-layered monolithic circuit structure, the method comprising the steps of:
(a) printing a circuit component onto an individual layer of thick film ceramic substrate;
(b) firing the individual layer of thick film ceramic substrate and the circuit component printed thereon;
(c) trimming the circuit component as necessary to achieve a desired degree of precision;
(d) applying a bonding agent to the individual layer of thick film ceramic substrate and assembling the individual layer of thick film ceramic substrate with one or more other layers of thick film ceramic substrate; and
(e) firing the assembled individual layer of thick film ceramic substrate and one or more other layers of thick film ceramic substrate together to activate the bonding agent, thereby bonding the individual layer of thick film ceramic substrate to the one or more other layers of thick film ceramic substrate and creating the multi-layered monolithic circuit structure

8. The method as set forth in claim 7, wherein the plurality of circuit components are selected from the group consisting of: resistors, capacitors, and inductors.

9. The method as set forth in claim 7, wherein the individual layers of thick film ceramic substrate are standard alumina thick film ceramic substrate.

10. The method as set forth in claim 7, wherein the bonding agent is a thick film glass.

11. A method of creating a multi-layered monolithic circuit structure, the method comprising the steps of:
(a) screen-printing a plurality of circuit components onto a plurality of individual layers of thick film ceramic substrate;
(b) firing the individual layers of thick film ceramic substrate and the circuit components screen-printed thereon;
(c) trimming the circuit components as necessary to achieve a desired degree of precision;
(d) applying a thick film glass bonding agent to the individual layers of thick film ceramic substrate and assembling the individual layers of thick film ceramic substrate; and
(e) firing the assembled individual layers of thick film ceramic substrate to sinter the thick film glass bonding agent, thereby bonding the individual layers of thick film ceramic substrate together and creating the multi-layered monolithic circuit structure.

12. The method as set forth in claim 11, wherein the plurality of circuit components are selected from the group consisting of: resistors, capacitors, and inductors.

13. The method as set forth in claim 11, wherein the individual layers of thick film ceramic substrate are standard alumina thick film ceramic substrate.

14. A method of creating a multi-layered monolithic circuit structure, the method comprising the steps of:
(a) screen-printing a plurality of circuit components onto a plurality of individual layers of substrate, wherein the circuit components are selected from the group consisting of: resistors, capacitors, and inductors, and wherein the individual layers of substrate are standard alumina thick film ceramic substrate;
(b) firing the individual layers of substrate and the circuit components screen-printed thereon;
(c) laser-trimming the circuit components as necessary to achieve a desired degree of precision;
(d) applying a thick film glass bonding agent to the individual layers of substrate and assembling the individual layers of substrate; and
(e) firing the assembled individual layers of substrate to sinter the thick film glass bonding agent, thereby bonding the individual layers of substrate together and creating the multi-layered monolithic circuit structure
